(19) United States
(12) Patent Application Publication
(10) Pub. No.: US 2004/0135208 A1
(43) Pub. Date: Jul. 15, 2004

(54) Semiconductor substrate and manufacturing method thereof

(75) Inventors: Katsuto Tanahashi, Kawasaki (JP); Hiroshi Kaneta, Kawasaki (JP); Tetsuo Fukuda, Kawasaki (JP)

Correspondence Address: WESTERMAN, HATTORI, DANIELS & ADRIAN, LLP, 1250 CONNECTICUT AVENUE, NW, SUITE 700, WASHINGTON, DC, 20036, US

(73) Assignee: FUJITSU LIMITED, Kawasaki (JP)

(21) Appl. No.: 10/743,793

(22) Filed: Dec. 24, 2003

(30) Foreign Application Priority Data
Dec. 27, 2002 (JP) 2002-381902

(51) Int. Cl. H01L 29/76; H01L 31/062; H01L 21/265

(52) U.S. Cl. 257/368; 257/375; 257/607; 257/608; 438/407; 438/520

(57) ABSTRACT

A semiconductor substrate of the present invention is a DSP wafer or Semi-DSP wafer (FIG. 2) having a flatness of an SFQR value ≦70 (nm) and containing boron at a concentration not lower than 5×10¹⁶ (atoms/cm³) nor higher than 2×10¹⁷ (atoms/cm³) within 95% or more of rectangular regions of 25×8 (mm²) arranged on a front face of the substrate. Specifically, a silicon crystal layer by an epitaxial growth is formed on a front face of a silicon substrate having the above substrate boron concentration.

### CROSS-REFERENCE TO RELATED APPLICATIONS

This application is based upon and claims the benefit of priority from the prior Japanese Patent Application No. 2002-381902, filed on Dec. 27, 2002, the entire contents of which are incorporated herein by reference.

### BACKGROUND OF THE INVENTION

1. Field of the Invention

The present invention relates to a semiconductor substrate having a front face and a rear face that are both mirror-polished, a semiconductor device using the same, and a manufacturing method of the semiconductor device.

2. Description of the Related Art

Conventionally, an epitaxial wafer (hereinafter called a “p/p⁺”), which is formed by epitaxially growing a silicon thin film on a front face of a silicon substrate containing boron (B) at a concentration of 1×10¹⁹ (atoms cm³), has been widely used as a semiconductor substrate for semiconductor integrated circuits. Boron and d-electron-based heavy metal atoms (for example, iron) have a function of forming a compound (iron and boron pairs) in silicon. The boron in silicon has, through the above function, an effect of sacking and capturing d-electron-based heavy metal contamination atoms, that is, a gettering effect (called boron gettering). This enables removal of heavy metal atoms, which are the most harmful to a device, from the active region of a semiconductor element, so as to improve the yield. A p⁺ substrate having boron at a high concentration and the p/p⁺ have great gettering abilities to d-electron-based heavy metal contamination atoms.

### SUMMARY OF THE INVENTION

A p/p⁺ has an oxide film formed by a low-temperature CVD (LTO: Low Temperature Oxide) formed on a rear face of a p⁺ substrate, in order to avoid autodoping during formation of an epitaxial film in which boron sputters from the rear face of the p⁺ substrate due to heating during the formation of an epitaxial film and captured in the epitaxial film to change the resistivity (boron concentration) thereof.

In International Technology Roadmap for Semiconductors (ITRS) for 2001, it is predicted that semiconductor integrated circuits having transistors with a minimum fabrication line width of 70 (nm) will become commercially practical in 2006, and so the SFQR (Site Front least sQuare Range) value needs to be reduced to at least 70 (nm) or lower for a silicon substrate for producing the transistor. This SFQR is a most frequently used parameter to indicate the flatness of a wafer, and is defined as an amplitude of a projection or depression on the front face of the wafer from a minimum square plane which is mathematically obtained in a region (typically a slit size of a scanning stepper: 25×8 (mm²)) on the front face of the wafer. The required value is semiempirically obtained from the performance of lithography required for microfabrication for 70 (nm) and, without meeting this value, it is impossible to manufacture a fine pattern (a gate electrode of the transistor in particular) in a desired size. It is widely recognized that a wafer without an SFQR value equal to a minimum fabrication line width generally causes defocus in the lithography process to bring about a pattern formation failure, and based on this recognition, ITRS requires wafer flatness.

As a silicon wafer for producing semiconductor integrated circuits, a single side polished (SSP) wafer is in wide use. The above-described p/p⁺ having the LTO film on the rear face is also included in the SSP wafer. As shown in FIG. 18, however, in development of 70 (nm)-generation semiconductor integrated circuits, only 40% of SSP wafers formed by conventional manufacturing methods meet SFQR values ≦70 (nm), which leads to a problem in which the SFQR values ≦70 (nm) cannot be fully achieved. In other words, it is impossible to manufacture devices conforming to the 70 (nm) rule at a high yield as long as using wafers produced by the prior art.

An example of manufacturing processes of the SSP wafer in the prior art will be briefly described hereinafter.

Manufacture of a silicon single crystal ingots [symbol] cutting into a cylindrical blocks [symbol] grinding the outer periphery of the cylindrical blocks [symbol] slicing with a wire saws [symbol] lapping [symbol] acid or alkali etching [symbol] single side polishing.

Manufacturing processes of an epitaxial wafer using the SSP wafer further include, after the above single side polishing,

deposition of an LTO film on the rear face [symbol] growth of an epitaxial silicon crystal layer on the front face.

In the above manufacturing processes, washing between the respective processes is omitted for simplification. What greatly affect the flatness of the SSP wafer among the processes are the acid or alkali etching after the lapping and the single side polishing.

The lapping can realize a significantly high flatness, but leaves on the front face of the wafer deflection and impurities, which need to be removed by performing the acid or alkali etching.

Since the acid etching is a diffusion controlled process, the non-uniformity of flow of an acid etching solution near the wafer has effect on the etching speed, so that projections and depressions are apt to appear due to uneven etching although the deflection and impurities can be removed. On the other hand, since the alkali etching is a surface reaction controlled process, the non-uniformity of flow of an etching solution has less effect, but the etching speed varies depending on anisotropy, that is, crystal orientation of silicon, so that projections and depressions are apt to appear on the front face due to anisotropy This cycle of the projections and depressions, however, is equal to or lower than one-several tenths of that due to the acid etching, and therefore the alkali etching or the alkali etching+the acid etching is mainly used in these days.

Although the deflection and impurities have been sufficiently removed from the wafer after completion of the etching as described above, the projections and depressions have appeared on both the front and rear faces thereof and, therefore, what removes these projections and depressions to realize a flat front face is the polishing explained below.

However, the single side polishing method is still a main technology at present, which is a method of polishing the front face with the rear face adhered or sacked to a ceramic plate. Accordingly, the front face becomes certainly flat after the polishing, but the flatness is kept only in the state of the rear face being adhered (or sacked) to the plate. When the wafer is detached from the plate, the projections and depressions on the rear face remain as they are even after completion of the polishing, so that part of them are transferred or printed through to the front face. This printing through causes projections and depressions on the front face and measured as the SFQR.

The foregoing shows that polishing of both the front and rear faces can realize a wafer with a significantly high flatness (a small SFQR value). The wafer having front and rear faces both of which have been polished is called a DSP (Double Side Polished) wafer. It is known that since the DSP wafer, however, has a contact area with an electrostatic chuck during dry etching much larger than that of the SSP wafer, a contact hole formed in the DSP wafer will greatly differ in diameter from that in the SSP wafer. It is also known that a de-chucking sequence from the electrostatic chuck for the DSP wafer is greatly different from that for the SSP wafer, and that the DSP wafer slips in a carrier system for the SSP wafer. these facts show that the use of the SSP wafer and the DSP wafer in the same device manufacturing line is difficult or leads to increased cost.

To achieve SFQR ≦70 (nm), it is obviously necessary, from the discussion in the above paragraph, to reduce the projections and depressions on the rear face of the wafer. One approach to the reduction is achieved by a method of polishing both faces. Based on measurement by the inventors, the DSP wafer meets SFQR ≦70 (nm) (see FIG. 1) and thus sufficiently meets the requirements for the 70 (nm)-generation lithography. As described in the above paragraph, however, there is a problem that it is difficult to use the DSP wafer in the same manufacturing process as that of the SSP wafer in the prior art.

What is devised to this problem is a wafer produced by lightly polishing the rear face of the conventional SSP wafer to partially remove the projections and depressions on the rear face (hereinafter this wafer being called a “Semi-DSP wafers”). This new SSP wafer also meets SFQR ≦70 (nm) (see Pig. 2). In addition, the projection and depression state of the rear face is close to that of the conventional SSP wafer to cause no trouble in device processes.

The above discussion shows the necessity to use the Semi-DSP wafer having a lightly polished rear face or a complete DSP wafer in order to achieve a sufficient flatness in lithography processes which manufacture future fine devices (specifically, for 70 (nm)-generation and thereafter).

However, there arises a new problem.from deposition of an LTO film on the rear face in a producing process of a p/p⁺ epitaxial wafer using the DSP wafer as a substrate, as shown below.

A possible processes including growth of the LTO film and growth of an epitaxial layer is one of:

\mathring{1} lapping [symbol] acid or alkali etching [symbol] rear face polishing [symbol] growth of an LTO film [symbol] front face polishing [symbol] growth of an epitaxial layer;

\mathring{2} lapping [symbol] acid or alkali etching [symbol] front face polishing [symbol] growth of an LTO film [symbol] rear face polishing [symbol] growth of an epitaxial layer;

\mathring{3} lapping [symbol] acid or alkali etching [symbol] both face polishing [symbol] growth of an LTO film [symbol] growth of an epitaxial layer; and

\mathring{4} lapping [symbol] acid or alkali etching [symbol] growth of an LTO film [symbol] both face polishing [symbol] growth of an epitaxial layer.

In \mathring{2} and \mathring{3}, however, at least a part of the front face needs to be supported with a jig or a susceptor during formation of the LTO film. This increases a risk of occurrence of a flaw on or adhesion of a foreign substance to the front face of the wafer, and thus causes the necessity of an additional polishing or a cleaning process for the front face, resulting in an increase in price of wafers.

Consequently, the manufacturing process of the epitaxial wafer using the Semi-DSP wafer or the DSP wafer as a substrate is limited only to \mathring{1} or \mathring{4}. In \mathring{4}, the used silicon wafer itself is the SSP wafer as it is, but the surface of the LTO film is polished, and thus the used wafer us substantially the DSP wafer.

The LTO film itself, however, is recently regarded as one of causes of the increase in price of wafers, so that an epitaxial wafer with no LTO film is under development.

Tamatsuka at al. devised a p/p⁺ epitaxial wafer with no LTO film formed thereon (see Japanese Patent Laid-open No. 2000-72595). In this case, the problem arising from formation of no LTO film is autodoping during formation of an epitaxial film. They eliminated the necessity of a measure against the autodoping by decreasing the concentration of boron in a p⁺ substrate from 1×10¹⁹ (atoms/cm³) in the prior art down to a range of not lower than 2.5×10¹⁸ (atoms/cm³) nor higher than 8×10¹⁸ (atoms/cm³). It is known that boron gettering never acts on elements other than d-electron-based ones (for example, molybdenum), and that gettering by oxygen precipitate is effective. Tamatsuka at al. also devised doping of impurity nitrogen during growth of the p⁺ substrate (crystal) in order to promote the formation of the oxygen precipitate and add oxygen precipitation gettering.

However, it was found that semiconductor integrated circuits manufactured using the p/p⁺ epitaxial wafer having no LTO film encounter a new problem of autodoping in a heating process (pointed out by Binns et al. in Japanese Patent Laid-open No. Sho 60-31231). The autodoping means that boron in a p⁺ substrate sputters from the rear face thereof and adheres to the front face of an adjacent water in a heating process for producing semiconductor integrated circuits to change the resistivity (boron concentration) of a region thereof where devices are to be produced. This brings about a situation of the devices not normally operating. Binns et al. show that whether or not autodoping occurs in the heating process depends on the kind of an atmospheric gas source in heating. When heat treatment is performed in an oxygen atmosphere, an oxide film is formed on the front face of the wafer. This oxide film has a function of preventing autodoping. On the other hand, when the heat treatment was performed in a nitrogen atmosphere, the occurrence of autodoping was found. The heating process for producing semiconductor integrated circuits is performed in various atmospheres and, therefore, it is desired to develop a wafer capable of avoiding the autodoping irrespective of an oxidizing or non-oxidizing atmospheric gas source.

It is an object of the present invention to provide a semiconductor substrate, a semiconductor device, and a manufacturing method thereof each of which meets the requirement for flatness in a lithography process of a 70 (nm)-generation and enables securement of a sufficient gettering ability while avoiding autodoping in a heating process irrespective of an oxidizing or non-oxidizing atmospheric gas source.

A semiconductor substrate of the present invention is a semiconductor substrate having a front face and a rear face that are both mirror-polished, wherein the semiconductor substrate meets an SFQR value ≦70 (nm) as a flatness of the front face, and contains boron at a concentration not lower than 5×10¹⁶ (atoms/cm³) nor higher than 2×10¹⁷ (atoms/cm³).

A semiconductor device of the present invention comprises a semiconductor element formed on the front face of the semiconductor substrate.

A manufacturing method of a semiconductor device of the present invention uses the semiconductor substrate to form a semiconductor element thereon.

A manufacturing method of a semiconductor substrate of the present invention comprises the steps of: forming a silicon wafer by doping with boron at a concentration not lower than 5×10¹⁶ (atoms/cm³) nor higher than 2×10¹⁷ (atoms/cm³); mirror-polishing a rear face of a front face of the silicon wafer, the front face being a face on which a crystal layer is to be formed; mirror-polishing the front face of the silicon wafer to achieve an SFQR value of the silicon wafer ≦70 (nm); and forming a crystal layer on the front face of the silicon wafer.

A manufacturing method of a semiconductor substrate of the present invention comprises the steps of: forming a silicon wafer by doping with boron; mirror-polishing both faces of the silicon wafer; and forming a crystal layer on one of the faces of the silicon wafer. wherein an SFQR value ≦70 (nm) is met, and a concentration of boron is made not lower than 5×10¹⁶ (atoms/cm³) nor higher than 2×10¹⁷ (atoms/cm³), by the mirror-polishing of both faces of the silicon wafer.

### BRIEF DESCRIPTION OF THE DRAWINGS

FIG. 1 is a characteristic chart showing the flatness of a silicon substrate of the present invention;

FIG. 2 is a characteristic chart showing the flatness of a wafer made by lightly polishing the rear face of an SSP wafer to partially remove projections and depressions on the rear face (called a “Semi-DSP” in the present invention);

FIG. 3 is a schematic plane view showing arrangement of flatness measurement regions (for a wafer having a diameter of 200 (mm));

FIG. 4 is a schematic cross-sectional view showing an example of a silicon substrate of a first embodiment;

FIG. 5 is a schematic view showing samples in a heat treatment furnace for evaluation of autodoping in a heating process;

FIGS. 6A and 6B are diagrams of heat treatment sequences used for evaluation of autodoping in heating processes;

FIG. 7 is a characteristic chart showing the boron concentration of a monitoring wafer;

FIG. 8 is a characteristic chart showing the boron concentrations ((a) 1000° C., (b) 1100° C.) of the monitoring wafer;

FIG. 9 is a characteristic chart showing the residual iron concentrations in surface layers of Samples B to G after forced contamination with iron element and dummy process heat treatment;

FIG. 10 is a characteristic chart showing the relationship between the epitaxial layer thickness and the substrate boron concentration of epitaxial wafers whose gettering abilities have been judged to be acceptable;

FIG. 11 is a characteristic chart showing the oxygen precipitation amounts before and after a dummy process heat treatment;

FIG. 12 is a schematic cross-sectional view showing another example of the silicon substrate of the first embodiment;

FIG. 13 is a schematic cross-sectional view showing another example of the silicon substrate of the first embodiment;

FIG. 14 is a schematic cross-sectional view showing another example of the silicon substrate of the first embodiment;

FIG. 15 is a schematic cross-sectional view showing another example of the silicon substrate of the first embodiment;

FIG. 16 is a schematic cross-sectional view showing another example of the silicon substrate of the first embodiment;

FIG. 17 is a schematic cross-sectional view showing a MOS transistor of a second embodiment; and

FIG. 18 is a characteristic chart showing the flatnesses of SSP wafers.

### DETAILED DESCRIPTION OF THE PREFERRED EMBODIMENTS

-Outline of the Present Invention-

The simplest method to avoid the autodoping in the heating process described in the paragraph of the description of the related art is to reduce the boron concentration in the p⁺ substrate. The reduction in the concentration of boron, however, may cause poor gettering ability by boron, leading to a malfunction of a semiconductor integrated circuit. The gettering ability of p/p⁺ is much higher than that at a reference level leading to a malfunction of the semiconductor integrated circuit. Accordingly. the reduction in the concentration of boron becomes possible by permitting a reduction in the gettering ability down to such a reference level. Hence, the present inventors decided to find an optimal boron concentration by reducing the concentration of boron in a p⁺ substrate (silicon wafer) to limit, quantitatively accurately, an optimal appropriate range of the boron concentration meeting two conflicting challenges of \mathring{1} avoidance of autodoping of boron in a heating process and \mathring{2} securement of a gettering ability enabling normal operation of a semiconductor integrated circuit, so as to meet the future requirement for SFQR values ≦70 (nm).

It is also known that boron becomes an oxygen precipitation nucleus (see, for example, Japan se Patent Laid-open No. Hei 10-50715 by Inaba et al.), and therefore the reduction in the concentration of boron leads to a reduction in nuclear density to cause insufficient oxygen precipitation and thus insufficient oxygen precipitation gettering. The present inventors observed, using an infrared absorption method, the effect of impurity carbon on the formation of oxygen precipitation nucleus (see Japanese Patent Laid-open No. Hei 11-204534). It was found that the oxygen precipitation nucleus in a CZ silicon crystal doped with the impurity carbon is a compound of carbon and oxygen. Hence, the present inventors devised application of carbon doping to a silicon substrate to be used for producing an epitaxial wafer in order to promote the formation of an oxygen precipitate which will be a gettering source of contamination metal other than d-electron-based ones (for example, molybdenum), in addition to the boron gettering. It is known (in the same document) that the effect of promoting the oxygen precipitation by carbon is hardly lost even if the heat treatment temperature in the device process is decreased to 800° C. or lower, and therefore there is no problem in application of the carbon doping to future processes.

The reduction in the concentration of boron in the epitaxial wafer has already been implemented. There is an already developed epitaxial wafer (called a p/p⁻ in relation to a p/p⁺) having a substrate boron concentration which has been reduced from 1×10¹⁹ (atoms/cm³) of the p⁺ down to 1×10¹⁵ (atoms/cm³). Because of the low boron concentration, the p/p⁻ causes no autodoping and thus has no LTO film on the rear face. The p/p⁻ cannot be expected at all to provide boron gettering that the p/p⁺ has. Hence, a technology has been developed that dopes a p⁻ substrate with nitrogen or carbon to promote oxygen precipitation so as to add an oxygen precipitation gettering ability thereto. The main point of the present invention is to achieve both avoidance of autodoping and securement of a gettering ability by optimizing the boron concentration, and further to enhance them by carbon doping. As for specifications of a wafer, the substrate boron concentration of an epitaxial wafer devised in the present invention is defined to fall within an intermediate region between those of the p/p⁺ and the p/p⁻.

Other than the above-described Japanese Patent Laid-open No. 2000-72595, there are many documents that describe the substrate boron concentration. The substrate boron concentration range of the present invention is an unused region that is not defined in the prior arts, and none of the above documents discloses or teaches on defining, based on the above-described point, the optimal range of the substrate boron concentration as strictly as the present invention does (see, for example, Japanese Patent Laid-open No. 2002-208596, Japanese Patent Laid-open No. Hei 10-229093, M. J. Binns, S. Kommu, M. R. Searcrist, R. W. Standley, R. Wise, D. J. Myers, D. Tisserand and D. Doyle, Electrochemical Society Proceedings Volume 2002-2, pp 682, The 57th Meeting of The Japan Society of Applied Physics and Related Societies, Extended Abstracts. 7p-ZG-5, and Y. Shirakawa, H. Yamada-Kaneta and H. Mori, J. Appl. Phys. 77, 41 (1996)). In addition, there is, of course, no prior art relating to carbon doping to the epitaxial wafer having such an intermediate boron concentration.

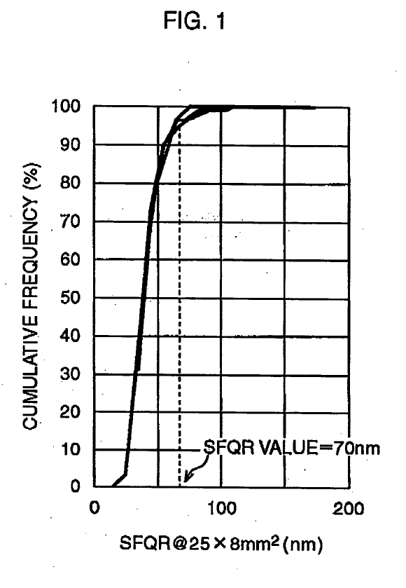

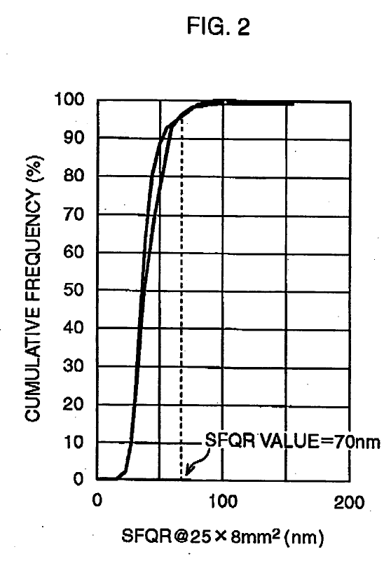

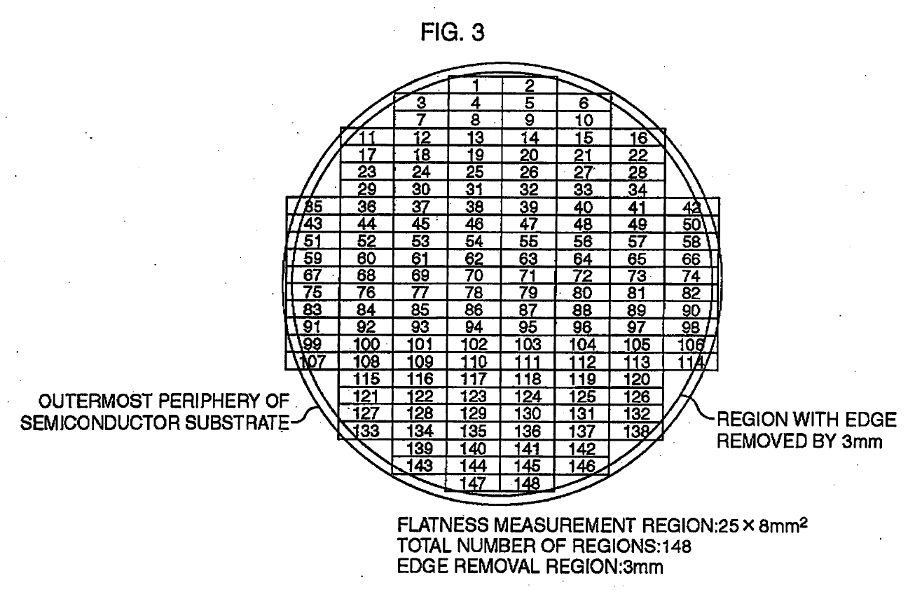

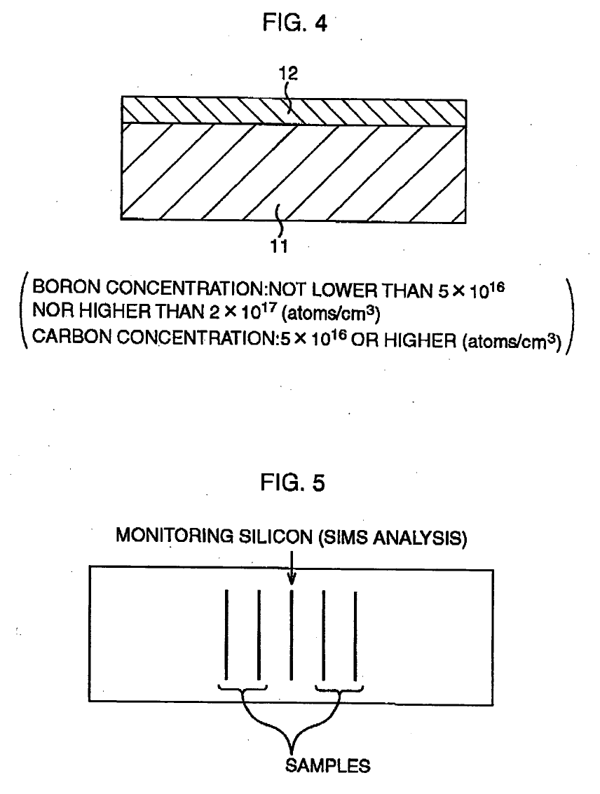

Specifically the semiconductor substrate of the present invention is a DSP wafer (FIG. 1) or a Semi-DSP wafer (FIG. 2) having a flatness of an SFQR value ≦70 (nm) and containing boron at a concentration not lower than 5×10¹⁶ (atoms/cm³) nor higher than 2×10¹⁷ (atoms/cm³) within 95% or more of rectangular regions of 25×8 (mm2) arranged on the front face of the substrate (FIG. 3). This silicon substrate, as shown in FIG. 4 as an example, is a DSP wafer or Semi-DSP wafer which meets the SFQR value ≦70 (nm) and in which a silicon crystal layer 12 by an epitaxial growth is formed on a front face of a silicon substrate 11 having the above substrate boron concentration.

The higher limit of the substrate boron concentration is defined here at 2×10¹⁷ (atoms/cm³) to enable \mathring{1} avoidance of autodoping of boron in an epitaxial growth process, and the lower limit is defined at 5×10¹⁶ (atoms/cm³) to enable \mathring{2} securement of a gettering ability by boron. Accordingly, the substrate boron concentration is strictly defined as described above so as to realize a device with high performance which applies to the rule of an SFQR value ≦70 (nm), that is, the minimum fabrication line width of 70 (nm) or less and meets both the above requirements of \mathring{1} and \mathring{2}. Further, the carbon concentration is defined to be 1×10¹⁵ (atoms/cm³) or higher, so that the gettering ability by the oxygen precipitate can be provided.

-Specific Embodiments of the Present Invention-

Specific embodiments of the present invention will be described hereinafter.

-First Embodiment-

A semiconductor substrate of the present invention will be explained in detail in this embodiment.

At the beginning, a manufacturing method of this semiconductor substrate will be briefly explained.

First, a silicon molten is doped with boron. At this time, the doping is controlled so that the concentration of boron in a silicon wafer to be formed is not lower than 5×10¹⁶ (atoms/cm³) nor higher than 2×10¹⁷ (atoms/cm³). Then, silicon crystals containing boron are grown by a pulling up method. Subsequently, a grown silicon ingot is processed into a wafer shape, etching using acid or alkali is performed after lapping, a rear face of a front face of a silicon wafer being a face on which a crystal layer is to be formed is mirror-polished, and subsequently the front face of the silicon wafer is mirror-polished. By the mirror-polishing of both the faces, the silicon wafer is made to have a SFQR value ≦70 (nm). A crystal layer, for example, an epitaxial layer by the epitaxial growth method is then formed on the front face of the silicon wafer.

Based on the above-described idea, the autodoping and gettering ability were evaluated to optimize the boron concentration. Table 1 is a list of samples used for the evaluation. All samples have a diameter of 200 (mm). As will be described later, the semiconductor substrate can be applied to any diameter without limitation even if it is 200 (mm), 300 (mm) or more. Incidentally, no LTO is formed on the rear face of each of Samples A to H.

TABLE 1

| | | | Epitaxial |
|---|---|---|---|
| | Boron | Carbon | Layer |
| | Concentration | Concentration | Thickness |
| Sample Name | (/cm³) | (/cm³) | (μm) |
| A | 8 × 10¹⁷ | 0 | 3 |
| B | 6 × 10¹⁷ | 0 | 3 |
| C | 2 × 10¹⁷ | 0 | 3 |
| D | 6 × 10¹⁷ | 0 | 5 |
| E | 5 × 10¹⁶ | 0 | 5 |
| F | 2 × 10¹⁷ | 0 | 10 |
| G | 5 × 10¹⁶ | 0 | 10 |
| H | 1 × 10¹⁵ | 5 × 10¹⁶ | 3 |

Table 1: List of samples used for evaluation of autodoping, gettering ability, and oxygen precipitation amount in a heating process.

The presence or absence of occurrence of autodoping in the heating process was examined using the above-listed samples.

As shown in FIG. 5, samples of the silicon substrate of the present invention with Nos. 1 to 4 were placed side by side, and a monitoring silicon wafer was placed between them. Since a heat treatment furnace for a diameter of 150 (mm) was used for the experiment, a silicon substrate with a diameter of 200 (mm) was divided into four pieces and introduced into the furnace. In the heating process, boron sputtering from the rear faces of Samples Nos. 1 to 4 adheres to the front face of the monitoring wafer. The boron concentration on the front face of the monitoring wafer was thus measured to evaluate the degree of autodoping.

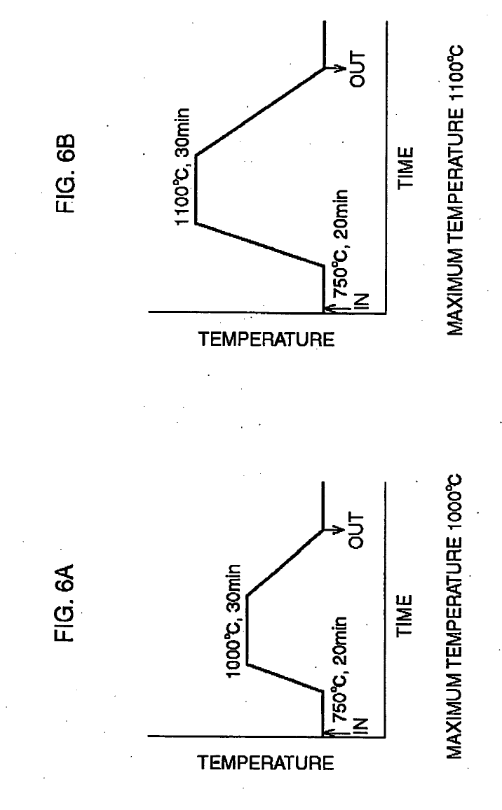

FIGS. 6A and 6B show heat treatment sequences in the heating process.

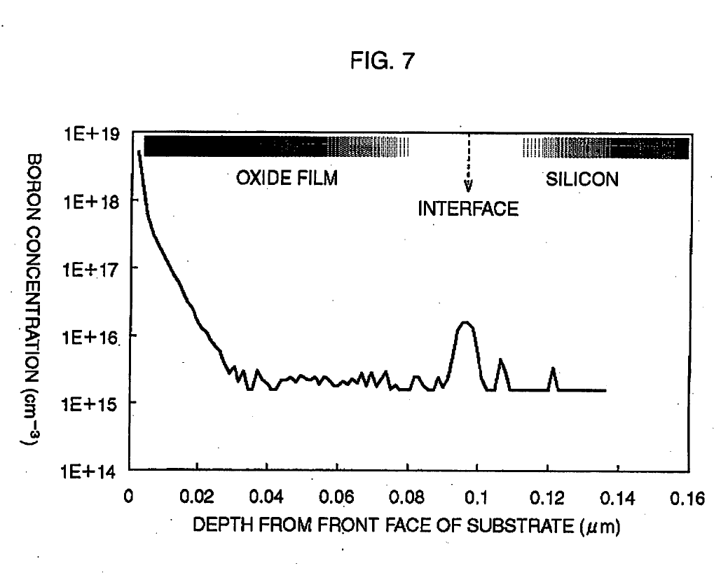

Experiments were carried out for 30 minutes as hold time in both cases at high temperatures of 1000° C. and 1100° C. An oxidizing or non-oxidizing gas atmosphere in heating was selectively used depending on purpose. FIG. 7 is a characteristic chart showing the boron concentration of a monitoring wafer when the heat treatment was performed on Sample A in the oxygen atmosphere under the condition shown in FIG. 6B. The boron concentration was measured using a secondary ion mass spectroscopy method (SIMS method).

FIG. 7 shows that boron sputtered from the rear face of Sample A during the heat treatment, adhered to the monitoring wafer, and diffused into the wafer, that is, autodoping during the heating process. It was confirmed, however, that the oxide film serves to prevent autodoping from the fact that most of boron was captured into the oxide film. Note that when the above experiments are carried out in a non-oxidizing atmosphere, the boron captured in the oxide film will diffuse into the substrate.

In FIG. 7, the dose amount of boron detected in the oxide film and at the interface between the oxide film and silicon substrate is 5.3×10¹¹ (atoms/cm²) that is not a negligible amount by any means. This means that Sample A is unacceptable regarding autodoping.

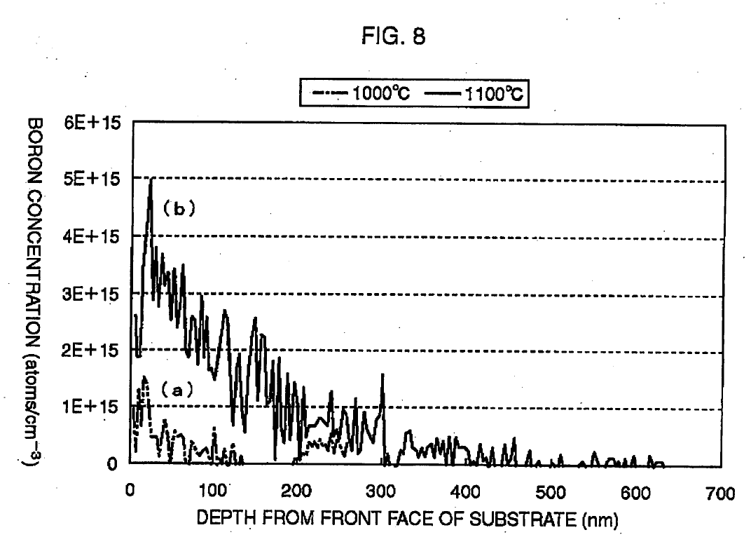

Hence, Sample B that has a next lower boron concentration than that of Sample A was used to examine autodoping again. In consideration of the result in FIG. 7, heat treatment was carried out in a nitrogen atmosphere (in a non-oxidizing atmosphere) that time. FIG. 8 shows the boron concentrations of the monitoring wafer in the cases of (a) 1000° C. and (b) 1100° C. In FIG. 8, the dose amounts are 5.3×10¹⁰ (atoms/cm²) for (a) and 5.8×10⁹ (atoms/cm²) for (b).

The dose amounts in FIG. 8 are reduced by an order of magnitude as compared to that in FIG. 7 and, therefore, can be judged that there is no autodoping problem in the heating process. As described above, the avoidance of autodoping was achieved by the reduction in the concentration of boron. Here, the number of boron atoms sputtering from the rear face of the silicon substrate during the heat treatment is proportional to the area of the substrate. Each sample employed for the experiment is one produced by dividing a substrate having a diameter of 200 (mm) into four pieces. With consideration of this, it is necessary to reduce the boron concentration of Sample B to a quarter for the avoidance of autodoping. In addition, it is necessary to further reduce the boron concentration of Sample B to four ninths when the diameter is 300 (mm) (the area ratio to the diameter of 200 (mm) is nine fourths).

On the other hand, an increase in spacing between the wafers in FIG. 5 decreases the probability of boron, which has sputtered from the rear face of the silicon substrate, flowing and adhering to the monitoring wafer. As a result, an increased boron concentration is permissible. The permissible increased boron concentration is simply proportional to the wafer spacing. While the wafer spacing is 5 (mm) since a furnace for a diameter of 150 (mm) is used this time, the wafer spacing is about two to three times the above in the case of a diameter of 200 (mm) or 300 (mm) or more, so that a permissible increased boron concentration is three times, at a maximum, that of the diameter of 150 (mm).

Regarding autodoping, it was judged that Sample A is unacceptable and Sample B is acceptable, and this is taken into consideration to define the acceptable and unacceptable concentrations regarding autodoping as,

unacceptable; (8×10¹⁷)×¼×4/9×3 =2.5×10¹⁷ (atoms/cm³), from Sample A, and

acceptable: (6×10¹⁷)×¼×4/9×3=2×10¹⁷ (atoms/cm³), from Sample B.

With a reduction in the concentration of boron in the substrate, the amount of boron sputtering during heating is reduced, so that the autodoping amount is reduced. Based on the above evaluation, silicon substrates having boron concentrations of 2×10¹⁷ (atoms/cm³) or lower can be evaluated as having no autodoping problem.

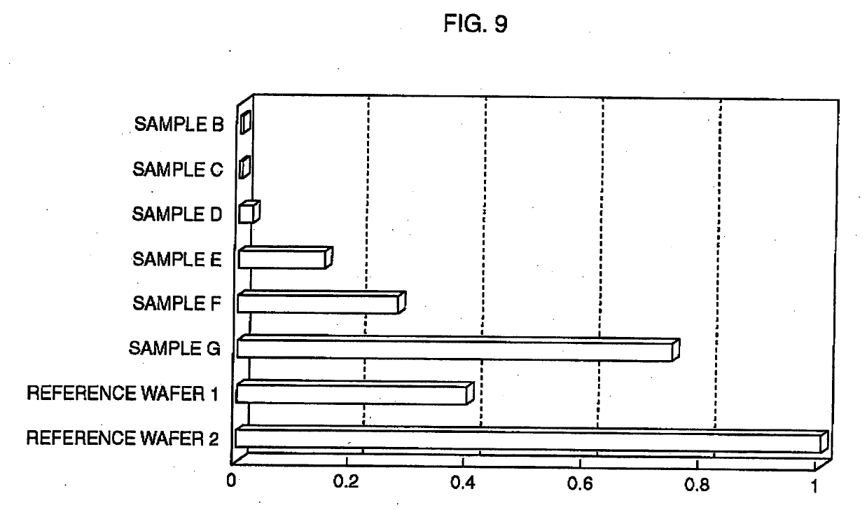

Next, gettering abilities were evaluated. The same amount of iron element was applied to Samples B to H using a spin coating method. Subsequently, a dummy heat treatment of the semiconductor device manufacturing process was carried out. It is needless to say that this heat treatment sequence is aimed at the 70 (nm)-generation process, that is, a low temperature process. After completion of the heat treatment, the residual iron concentrations in surface layers were measured using a DLTS (Deep Level Transient Spectroscopy) method. FIG. 9 shows the surface layer residual iron concentrations of Samples B to G. A lower surface layer residual iron concentration indicates that more iron element has been gotten into the wafer and, therefore, means that the wafer has a higher gettering ability.

In FIG. 9, reference wafers 1 and 2 are silicon wafers which have been used for producing semiconductor integrated circuits having transistors with minimum fabrication line widths of 90 (nm) to 100 (nm) or more. Samples B to G are the same as Samples B to G shown in Table 1. A target gettering ability to be added to a wafer is that of the reference wafer 1 or 2, and thus when a wafer has a residual iron concentration value that shown by the reference wafer 1 or the reference wafer 2, the wafer has a sufficient gettering ability. Accordingly, FIG. 9 shows that Samples B to G have gettering abilities at about a reference level which enables normal operation of the semiconductor integrated circuits.

FIG. 9 also shows that the gettering ability of an epitaxial wafer depends on both the substrate boron concentration and the epitaxial layer thickness. With a thinner epitaxial layer thickness, an epitaxial wafer has a shorter distance from the surface to its gettering sink (epitaxial substrate) and thus has a higher gettering ability (in comparison between, for example, Samples B and D, or C and F, or E and G in FIG. 9). For the same epitaxial layer thickness, an epitaxial wafer with a higher substrat boron concentration has a gettering sink present at a higher density and thus has a higher gettering ability (in comparison between, for example, Samples B and C, or D and E, or F and G in FIG. 9).

The above shows that an epitaxial wafer having a boron concentration of 5×10¹⁶ (atoms/cm³) as Sample G does obtains a minimum sufficient gettering ability.

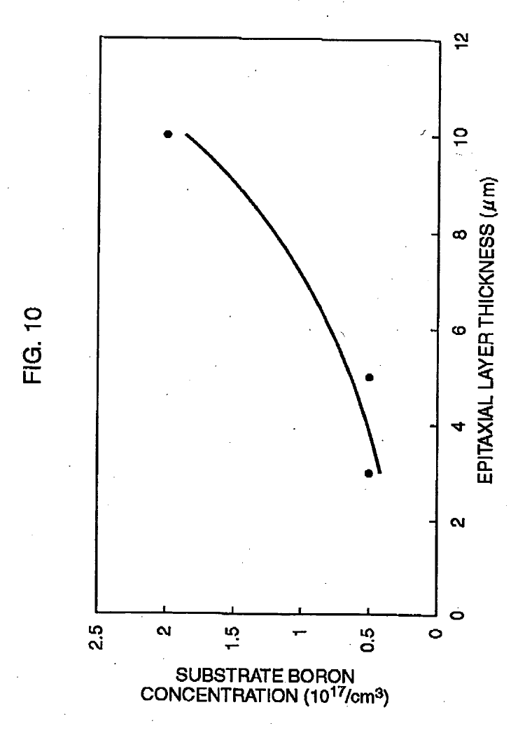

FIG. 10 is a characteristic chart made by plotting substrate boron concentrations for various epitaxial layer thicknesses when epitaxial wafers have gettering abilities superior to that of the reference wafer 1 (or have residual iron concentrations lower than that of the reference wafer 1).

Since there was no sample with a thickness of a silicon crystal layer (epitaxial layer thickness) of 3 μm or 5 μm that has a residual iron concentration exceeding that of the reference wafer 1, the minimum value among the substrate boron concentrations of the experimental samples was used. FIG. 10 shows acceptable gettering abilities provided by epitaxial thicknesses t (μm) and substrate boron concentrations [B] (atoms/cm³) by Equation (1)

[B]≧(2.2±0.2)×10¹⁶ exp (0.21 t) (1).

This shows that when the epitaxial layer thickness is t (μm), the substrate boron concentration only needs to be [B] (atoms/cm³) or more. Conversely, it is shown that when the substrate boron concentration is [B] (atoms/cm3), the epitaxial layer thickness only needs to be t (μm) or less.

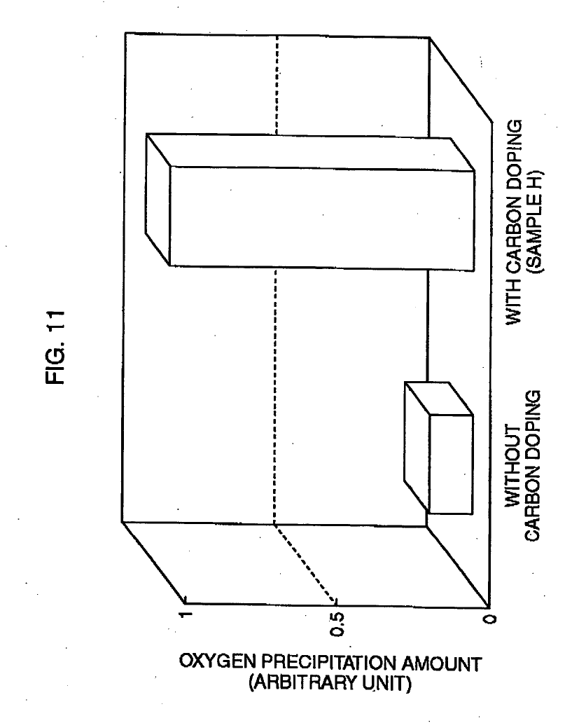

FIG. 11 is a characteristic chart showing the oxygen precipitation amounts for Sample E before and after a dummy heat treatment of the semiconductor element manufacturing process.

The oxygen concentrations of the sample before and after the heat treatment were measured using a Fourier transform infrared spectrophotometer to obtain the difference therebetween. The oxygen precipitation amount of a sample doped with carbon (substrate carbon concentration=5×10¹⁶ (atoms/cm³)) is about ten times that of an undoped sample. A precipitation promoting effect by carbon doping was observed.

The present invention should not be limited to this embodiment. The above-described embodiment only shows the case in which the semiconductor substrate of the present invention is applied to an epitaxial wafer, and therefore anything that has the same aspects as those described in the claims of the present invention and provides similar effects should be included in the technical scope of the present invention.

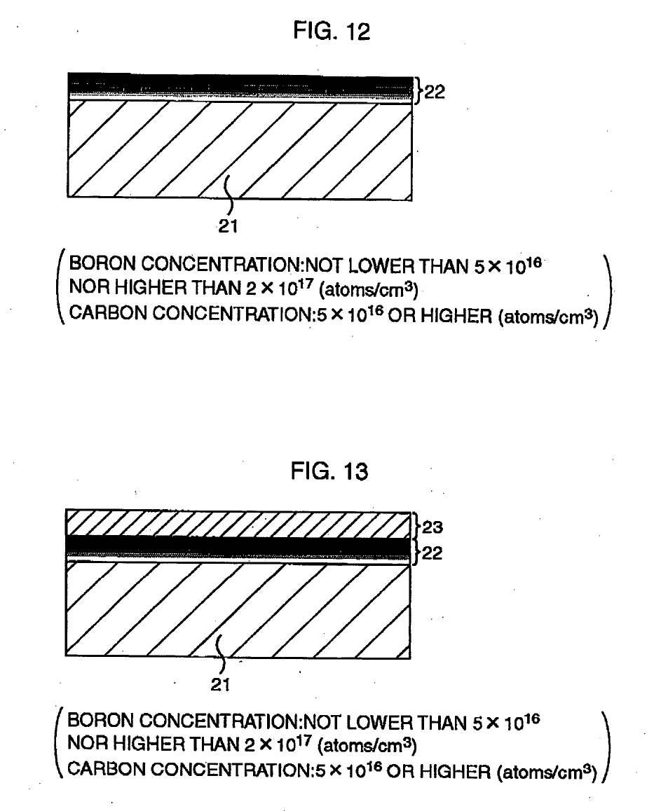

A silicon substrate 21, for example, as shown in FIG. 12, which is doped with boron and carbon within respective concentration ranges of the present invention and meets the SFQR value ≦70 (nm) provides an expected sufficient effect of gettering even if a silicon-germanium alloy crystal layer 22 is formed thereon, and is thus suitable for manufacturing 70 (nm)-generation devices. This applies to a semiconductor substrate with a silicon crystal layer 23 further formed on a front face of the alloy crystal layer 22 as shown in FIG. 13. These two kinds of semiconductor substrates are called strained silicon wafers and expected for use in manufacturing future high-speed devices.

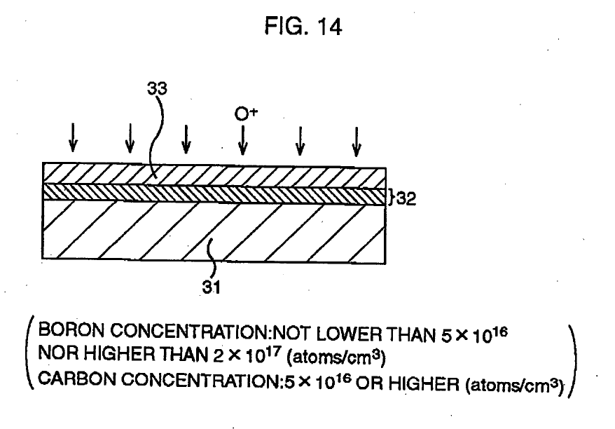

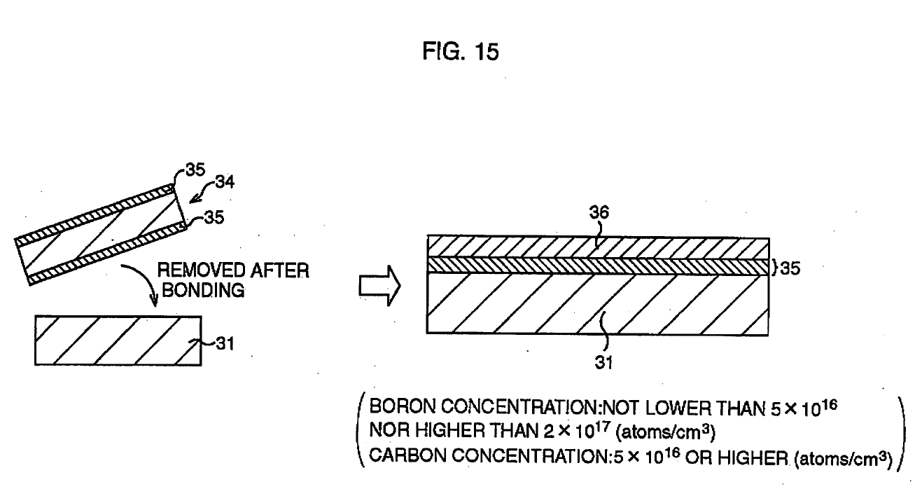

Further, as shown in FIG. 14 and FIG. 15, SOI (Semiconductor On Insulator) substrates can also be manufactured by an SIMOX method or a bonding method using a silicon substrate 31 which is doped with boron and carbon within the concentration ranges of the present invention and meets the SFQR value ≦70 (nm).

In the SIMOX method, as shown in FIG. 14, oxygen ions are introduced here into the silicon substrate 31 to form a silicon oxide layer 32, thereby forming a silicon crystal layer 33 on the silicon substrate 31 via the silicon oxide layer 32.

First, a silicon molten is doped with boron. At this time, the doping is controlled so that the concentration of boron in a silicon wafer to be formed is not lower than 5×10¹⁶ (atoms/cm³) nor higher than 2×10¹⁷ (atoms/cm³). Then, silicon crystals containing boron are.grown by the pulling up method. Subsequently, a grown silicon ingot is processed into a wafer shape, etching using acid or alkali is performed after lapping, a rear face of a front fac of a silicon wafer being a face on which a crystal layer is to be formed is mirror-polished, and subsequently the front face of the silicon wafer is mirror-polished. By the mirror-polishing of both the faces, the silicon wafer is made to have a SPQR value ≦70 (nm). oxygen ions are then introduced into the silicon wafer to form a silicon oxide layer, and thereafter a crystal layer, for example, an epitaxial layer by the epitaxial growth method is formed on the front face of the silicon wafer.

In the bonding method, as shown in FIG. 15, a silicon substrate 34 having thermally oxidized layers 35 on its front and rear faces is bonded to the top of the silicon substrate 31, and then the thermally oxidized film 35 on the front face and the silicon are removed to form a silicon crystal layer 36 on the silicon substrate 31 via the thermally oxidized layer 35. These cases can also obviously provide expected gettering abilities by effects of boron and carbon.

First, a silicon molten is doped with boron. At this time, the doping is controlled so that the concentration of boron in a silicon wafer to be formed is not lower than 5×10¹⁶ (atoms/cm³) nor higher than 2×10¹⁷ (atoms/cm3). Then, silicon crystals containing boron are grown by the pulling up method. Subsequently, a grown silicon ingot is processed into a wafer shape, etching using acid or alkali is performed after lapping, a rear face of a front face of a silicon wafer being a face on which a crystal layer is to be formed is mirror-polished, and subsequently the front face of the silicon wafer is mirror-polished. By the mirror-polishing of both the faces, the silicon wafer is made to have a SFQR value ≦70 (nm). Another silicon wafer is then bonded to the silicon wafer as described above, and the bonded silicon wafer is partially removed.

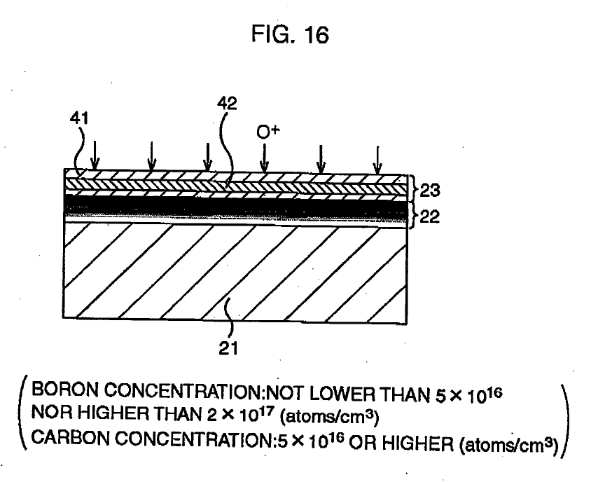

Further, a strained SOI substrate made by combining a strained silicon wafer and an SOI structure can also provide the effect of the present invention. This semiconductor substrate is made, in particular, as shown in FIG. 16, by forming the silicon crystal layer 23 on the front face of the alloy crystal layer 22 in FIG. 13, and then forming a silicon oxide layer 42 in the silicon crystal layer 23 through use of, for example, the SIMOX method. As a result, the silicon crystal layer 23 is formed to have a silicon crystal layer 41 on the silicon oxide layer 42.

As a matter of fact, developments regarding the Sol substrate are focused on solution of problems with the manufacturing method thereof, and there is no effective method found regarding gettering of the SOI substrate. The use of the silicon substrate of the present invention for various SOI substrates leads to SOI substrates that are given gettering abilities, so that improvements in reliability of various devices can be realized.

As is clear from the above discussion, the silicon substrate of the present invention can be embodied to any diameter without limitation even if it is 200 (mm), 300 (mm) or more.

-Second Embodiment-

In this embodiment, a semiconductor device in which a semiconductor element is formed using the semiconductor substrate described in the first embodiment and a manufacturing method thereof will be explained in detail. The semiconductor substrate shown in FIG. 4 is exemplarily shown as a semiconductor substrate to describe the formation of a MOS transistor. It should be noted that the present invention is applicable not only to the MOS transistor but also to other overall semiconductor devices.

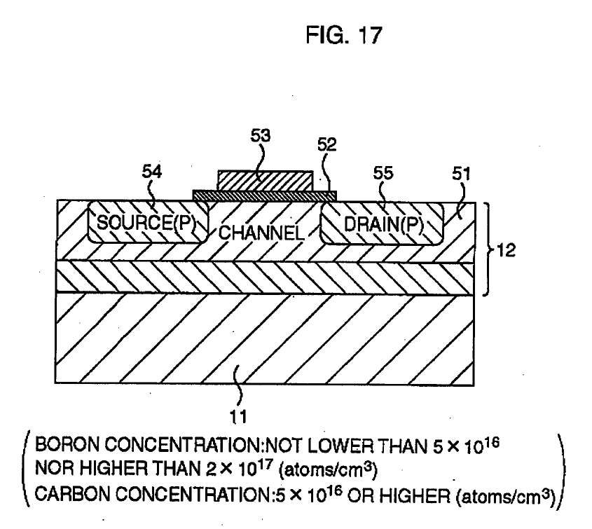

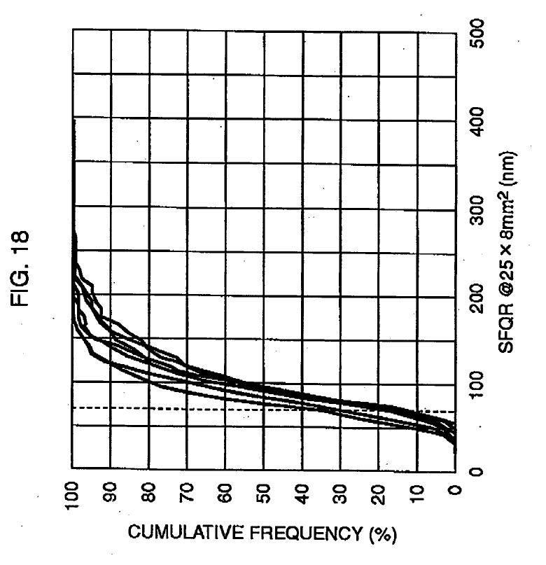

FIG. 17 is a schematic cross-sectional view showing a MOS transistor of a second embodiment.

This MOS transistor is a so-called p-type MOS transistor in which, in the semiconductor substrate having the silicon crystal layer-(epitaxial layer) 12 formed on the silicon substrate 11 described with FIG. 4 of the first embodiment, an n-well 51 is formed in the silicon crystal layer 12 by ion-implanting n-type impurities, a gate insulation film 52 and a gate electrode 53 are patterned on the silicon crystal layer 12, and a source 54 and a drain 55 are formed by ion-implanting p-type impurities using the gate electrode 53 as a mask.

According to this embodiment, it is possible to use, as a semiconductor substrate for producing a semiconductor integrated circuit, an epitaxial wafer that can ensure an sufficient gettering ability while avoiding autodoping in the heating process irrespective of an oxidizing or non-oxidizing atmospheric gas source in a heating process for producing a semiconductor integrated circuit, and meets the flatness required for a 70 (nm)-generation. This enables manufacture of a semiconductor integrated circuit having a MOS transistor with a minimum fabrication line width of 70 (nm).

According to the present invention, realized is a semiconductor substrate that meets the requirement for flatness in a lithography process of a 70 (nm)-generation and enables securement of a sufficient gettering ability while avoiding autodoping in a heating process irrespective of an oxidizing or non-oxidizing atmospheric gas source, so that a semiconductor device with a minimum fabrication line width of 70 (am) using the semiconductor substrate can be manufactured.

The present embodiments are to be considered in all respects as illustrative and no restrictive, and all changes which come within the meaning and range of equivalency of the claims are therefore intended to be embraced therein. The invention may be embodied in other specific forms without departing from the spirit or essential characteristics thereof.

What is claimed is:

1. A semiconductor substrate comprising
a front face and a rear face that are both mirror-polished,
wherein said semiconductor substrate meets an SFQR values ≦70 (nm) as a flatness of the front face, and contains boron at a concentration higher than or equal to 5×10¹⁶ (atoms/cm³) lower than or equal to 2×10¹⁷ (atoms/cm³).

2. The semiconductor substrate according to claim 1, wherein a crystal layer is provided on the front face.

3. The semiconductor substrate according to claim 2, wherein a minimum value of the concentration of boron [B] (atoms/cm³) is defined for a required thickness t (μm) of the crystal layer, based on a relational equation
[B]≧(2.2±0.2)×10¹⁶ exp (0.21 t).

4. The semiconductor substrate according to claim 2 wherein a maximum value of a thickness t (μm) of the crystal layer is defined for a required concentration of boron [B] (atoms/cm³), based on a relational equation
[B]≧(2.2±0.2)×10¹⁶ exp (0.21 t).

5. The semiconductor substrate according to claim 2, wherein the crystal layer is a silicon crystal layer formed by epitaxial growth.

6. The semiconductor substrate according to claim 2, wherein the crystal layer is a silicon-germanium alloy crystal layer.

7. The semiconductor substrate according to claim 2, wherein the crystal layer is a layer in a layered structure of a silicon-germanium alloy crystal layer and a silicon crystal layer.

8. The semiconductor substrate according to claim 7, wherein the silicon crystal layer is formed in an SOI structure in which the silicon crystal layer is separated by a silicon oxide layer.

9. The semiconductor substrate according to claim 2,
wherein said semiconductor substrate is an SOI substrate; and
wherein the crystal layer is an upper silicon crystal layer separated by a silicon oxide layer.

10. The semiconductor substrate according to claim 9, wherein the SOI substrate is formed by a SIMOX method.

11. The semiconductor substrate according to claim 9, wherein the SOI substrate is formed by a bonding method.

12. The semiconductor substrate according to claim 1, wherein the rear face is in an exposed state, or a natural oxide film having a thickness of 1 (nm) or less is formed on the rear face.

13. The semiconductor substrate according to claim 1, wherein carbon is contained at a concentration of 1×10¹⁵ (atoms/cm³) or higher.

14. A semiconductor device, comprising:
a semiconductor substrate having a front face and a rear face that are both mirror-polished, said semiconductor substrate meeting an SFQR value ≦70 (nm) as a flatness of the front face, and containing boron at a concentration higher than or equal to 5×10¹⁶ (atoms/cm³) lower than or equal to 2×10¹⁷ (atoms/cm³); and
a semiconductor element formed on the front face of said semiconductor substrate.

15. A manufacturing method of a semiconductor substrate, comprising the steps of:
forming a silicon wafer by doping with boron at a concentration higher than or equal to 5×10¹⁶ (atoms/cm³) lower than or equal to 2×10¹⁷ (atoms/cm³);
mirror-polishing a rear face of a front face of the silicon wafer, the front face being a face on which a crystal layer is to be formed;
mirror-polishing the front face of the silicon wafer to achieve an SFQR value of the silicon wafer≦70 (nm); and
forming a crystal layer on the front face of the silicon wafer.

16. The manufacturing method of a semiconductor substrate according to claim 15, wherein the crystal layer is a silicon-germanium alloy crystal layer.

17. A manufacturing method of a semiconductor substrate, comprising the steps of:
forming a silicon wafer by doping with boron;
mirror-polishing both faces of the silicon wafer; and
forming a crystal layer on one of the faces of the silicon wafer,
wherein an SFQR value ≦70 (nm) is met, and a concentration of boron is made higher than or equal to 5×10¹⁶ (atoms/cm³) lower than or equal to 2×10¹⁷ (atoms/cm³), by the mirror-polishing of both faces of the silicon wafer.

18. The manufacturing method of a semiconductor substrate according to claim 17, wherein the crystal layer is a silicon-germanium alloy crystal layer.
